(19) United States
(12) Patent Application Publication
(10) Pub. No.: US 2018/0363141 A1
(43) Pub. Date: Dec. 20, 2018

(54) FACILITY FOR TREATING CONTAINERS BY MICROWAVE PLASMA, COMPRISING A SOLID-STATE GENERATOR AND ADJUSTMENT METHOD

(71) Applicant: SIDEL PARTICIPATIONS, Octeville-Sur-Mer (FR)

(72) Inventors: Yves-Alban DUCLOS, Octeville-Sur-Mer (FR); Denis TURLOTTE, Octeville-Sur-Mer (FR)

(21) Appl. No.: 15/571,684

(22) PCT Filed: Apr. 22, 2016
(86) PCT No.: PCT/FR2016/050956

§ 371 Date: Nov. 3, 2017

(30) Foreign Application Priority Data
May 4, 2015 (FR) 1553966

(51) Int. Cl. C23C 16/511; C23C 16/04; C23C 16/26; C23C 16/52; H01J 37/32

(52) U.S. Cl. CPC C23C 16/511; C23C 16/045; H01J 37/32972; C23C 16/52; H01J 37/32266; C23C 16/26

(57) ABSTRACT

Disclosed is a facility for plasma-assisted chemical vapor deposition, on an inner wall of a polymer container, of a thin barrier layer, and a method for adjusting the facility. The facility includes: an enclosure mounted in a conductive recess; a device for injecting precursor gas into the enclosure; a microwave generator; and a device for diffusing microwaves in the enclosure, connected to the microwave generator, energizing and maintaining a plasma in the precursor gas. The solid-state microwave generator has variable microwave emission frequency. The facility includes a sensor measuring the energy intensity of the plasma produced in the container. The facility includes a control unit connected to the sensor and to the microwave generator, the control unit being programmed to adjust the microwave emission frequency, via the variable frequency drive, in accordance with the value of the physical quantity characterizing the energy intensity measured by the sensor.

The invention relates to the plasma treatment of containers made of polymer (such as PET), and more specifically by plasma-assisted chemical vapor deposition of a thin layer—typically (but not exclusively)—of hydrogenated amorphous carbon.

A hydrogenated amorphous carbon is a material comprising carbon and hydrogen atoms, which are currently designated by the formula a-C:H, which appears in the center of the carbon-hydrogen ternary equilibrium phase diagram, as illustrated in particular in the Encyclopédie Ullmann de l'industrie chimique (Ullmann's Encyclopedia of Industrial Chemistry), 5^{th} Edition, Vol. A26, p. 720.

The thin (with a thickness of between 0.050 μm and 0.200 μm) layers (or films) of hydrogenated amorphous carbon have the ability to form a barrier particularly to ultraviolet light, oxygen molecules and carbon dioxide molecules. In the absence of such a barrier layer, the ultraviolet light and oxygen pass through the wall of the container and are able to corrupt its contents, particularly beer or tea. As for the carbon dioxide of carbonated (so-called gaseous) beverages, it also has a tendency to escape by migration through the wall of the container.

Traditionally, and as described in particular in the European patent EP 1 068 032 (Sidel Participations) or in the Japanese patent JP 2006-336095 (Toppan Printing), to form a thin layer on the inner wall of a container, the first step is to introduce the container into an enclosure placed in a cavity that is conductive and transparent to most of the microwave spectrum.

Then, the container and the enclosure are depressurized at the same time to obtain, on the one hand, in the container, a high vacuum (of several μbars—it will be recalled that 1 μbar=10⁻⁶ bar) necessary for the establishment of the plasma and, on the other hand, in the enclosure on the outside of the container, a medium-level vacuum (on the order of 30 mbar to 100 mbar), to prevent the container from contracting under the effect of the pressure difference on both sides of its wall.

Then, injected into the container is a precursor gas (typically a hydrocarbon in gaseous form, such as acetylene, C₂H₂), and then generated in the cavity (and therefore in the enclosure) is an electromagnetic microwave field to activate (and sustain for a predetermined period, generally on the order of several seconds) in the gas a plasma that separates the molecules from the gas and then recombines them into various species (particularly CH, CH₂, CH₃ in the case of a hydrocarbon such as acetylene) that are deposited in a thin layer on the inner wall of the container.

In the known methods, the microwaves are generally produced by a magnetron, connected to the cavity by a wave guide. This proven technique, however, does not work without drawbacks.

So that these microwaves are correctly diffused in the cavity (and therefore in the enclosure), the resonance frequency thereof must correspond to a transmission frequency peak of the magnetron. Now, not only is the peak frequency of the microwaves produced by a magnetron not adjustable, but this peak, which is in a rather wide transmission spectrum (on the order of 50 MHz), is no longer entirely stable, because it depends in particular on factors that can vary, such as temperature, electrical voltage or even the intensity of the control current.

Since, in practice, the dimensional characteristics of the cavities and the transmission frequencies of the magnetrons have slight variations, the assembly of the machines for plasma treatment of the containers therefore necessarily comprises an operation for pairing each cavity with a magnetron.

Statistically, only one magnetron in four is suitable for a given cavity: therefore, it is understood that the assembly of a machine for plasma treatment of containers is not simple. A poor pairing leads to a poor activation and/or a poor sustaining of the plasma, which can in particular undergo flickering or intensity drops, resulting in a poor treatment of the containers that must consequently be discarded.

A first objective is to propose a solution that makes it possible to enhance reliability of the machines for plasma treatment of the containers.

A second objective is to propose a solution that makes it possible to simplify the assembly of the machines for plasma treatment of the containers.

A third objective is to improve the quality of the plasma treatment of the containers.

A fourth objective is to make possible an improved activation and an improved sustaining of the plasma.

For this purpose, firstly there is proposed an installation for the plasma-assisted chemical vapor deposition—on an inner wall of a container made of polymer—of a thin barrier layer, which comprises:
a conductive cavity;
an enclosure mounted in the cavity;
a device for injecting a precursor gas into the enclosure;
a generator of microwaves;
a device for diffusion of the microwaves in the enclosure, connected to the microwave generator, to excite and sustain a plasma in the precursor gas;
   this installation being characterized:
in that the microwave generator is a solid-state generator, equipped with a variable frequency drive for transmission of microwaves;
in that it comprises a sensor positioned so as to measure a physical magnitude characterizing the energy intensity of the plasma produced in the container;
in that it comprises a control unit connected to the sensor and to the microwave generator, this control unit being programmed to adjust the transmission frequency of the microwaves, by means of the variable frequency drive, as a function of the value of the physical magnitude characterizing the energy intensity measured by the sensor.

Various additional characteristics can be specified, alone or in combination:
the physical magnitude measured is the luminosity of the plasma, and the sensor is a luminosity sensor directed toward the enclosure so as to measure the luminosity through the wall of the enclosure and that of the container;
the physical magnitude measured is the mass concentration of the species contained in the plasma and the sensor is a spectrometer;
the physical magnitude measured is the pressure of the plasma, and the sensor is a sensor of the pressure prevailing in the container;
the device for diffusion of the microwaves appears in the form of an antenna;
the antenna extends through the cavity and projects into it;
the antenna forms a loop in the cavity;
the dimensions of the loop formed by the antenna are of the same order of magnitude as the half-wavelength of the microwaves produced by the generator;
the device for diffusion of the microwaves is connected to the generator by a coaxial cable.

Secondly, there is proposed a method for adjusting an installation as presented above, which comprises the operations consisting in:
introducing a container into the enclosure;
injecting the precursor gas into the container;
generating in the enclosure, by means of the microwave generator, an electromagnetic field with a predetermined transmission frequency so as to excite a plasma in the precursor gas;
measuring, by means of the sensor, a physical magnitude characterizing the energy intensity of the plasma produced in the container;
as long as the physical magnitude characterizing the energy intensity of the plasma produced in the enclosure differs from a predetermined reference value, adjusting the transmission frequency of the microwaves by means of the control unit acting on the variable frequency drive.

According to other characteristics of the method, taken alone or in combination:
the physical magnitude measured is proportional to the value of the energy intensity; the physical magnitude measured is the luminosity of the plasma; the physical magnitude measured is the mass concentration of the species contained in the plasma;
the physical magnitude measured is inversely proportional to the energy intensity; the physical magnitude measured is the pressure prevailing in the container.

Other objects and advantages of the invention will emerge from the description of an embodiment, given below with reference to the accompanying drawings in which:

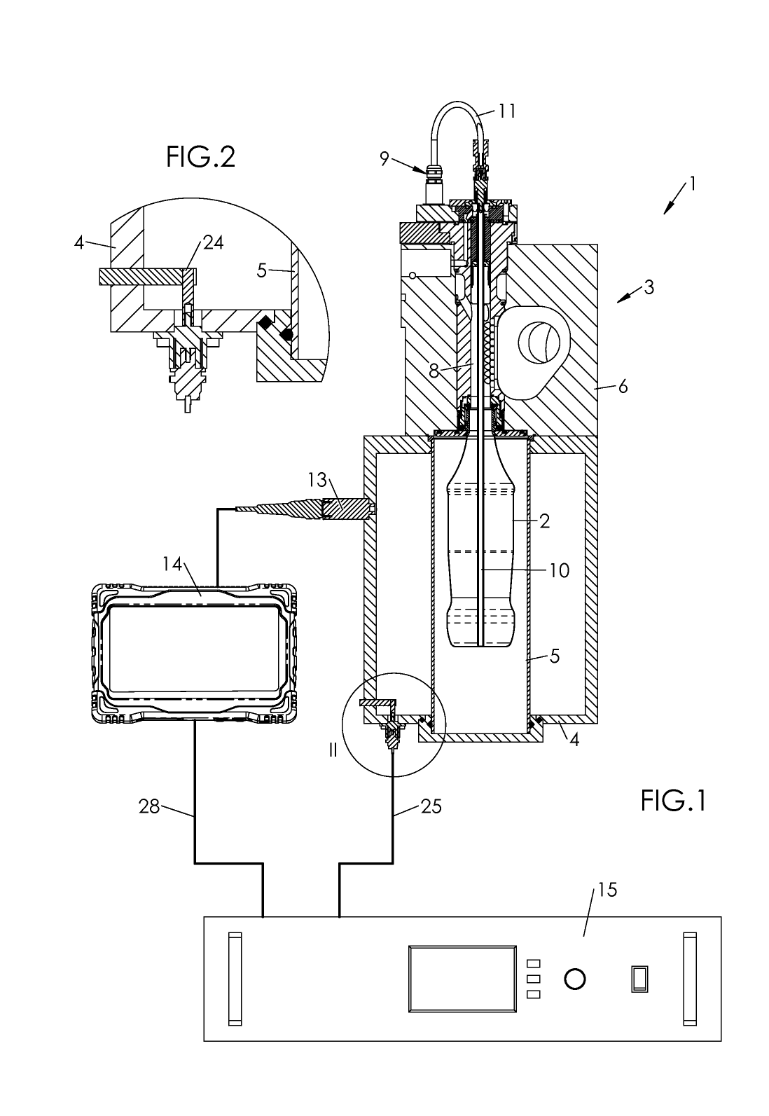

FIG. 1 is a cutaway view, partially diagrammatic, of an installation for plasma treatment of containers, comprising a station for treating a container;

FIG. 2 is a view of a detail, on a larger scale, of the treatment station shown in FIG. 1, according to the inset II;

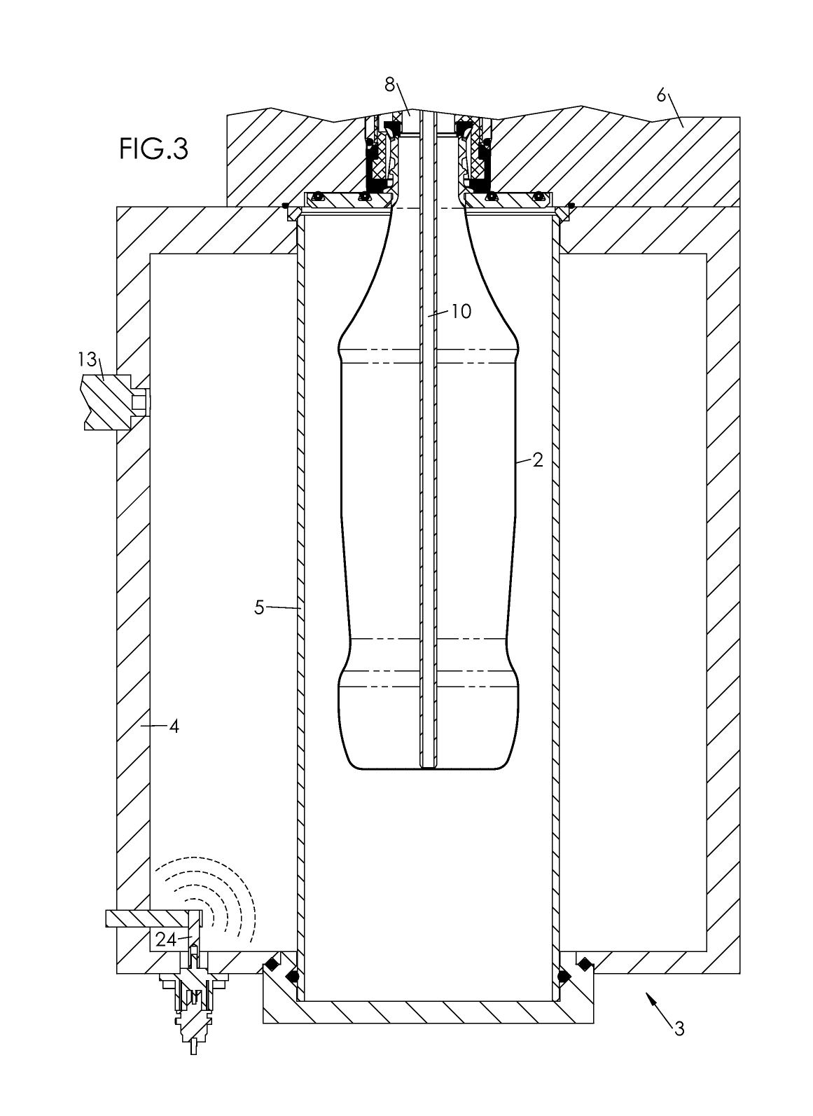

FIG. 3 is a partial cutaway view, on a larger scale, of the treatment station shown in FIG. 1;

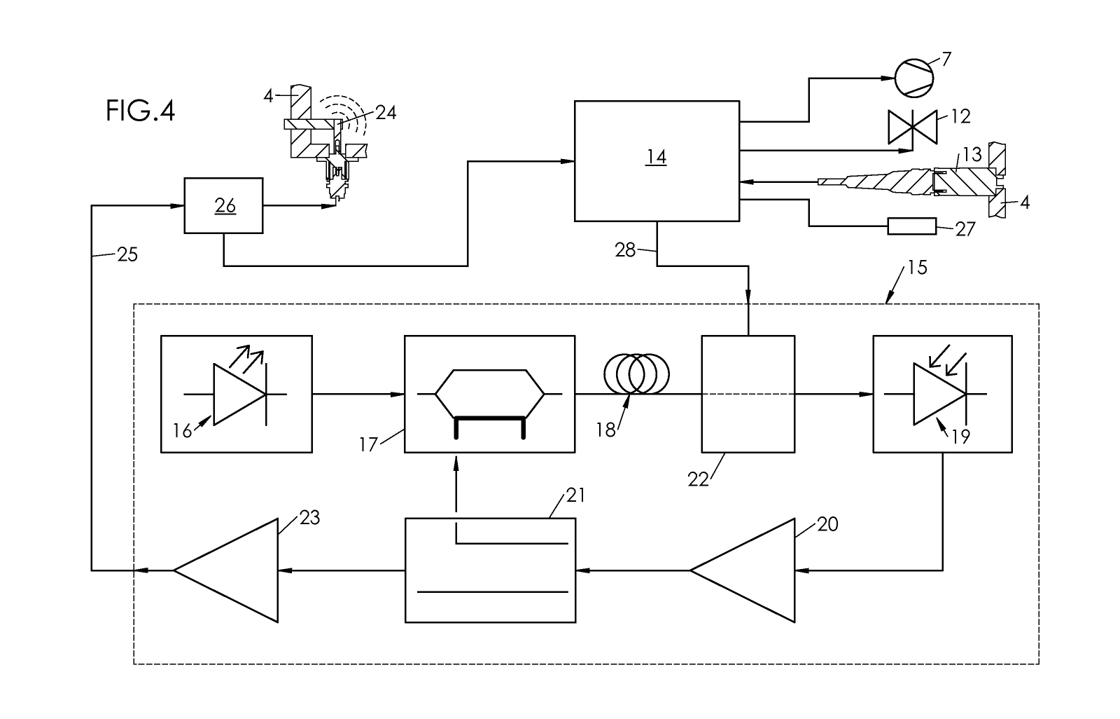

FIG. 4 is a diagram illustrating the functional structure of the treatment installation of FIG. 1;

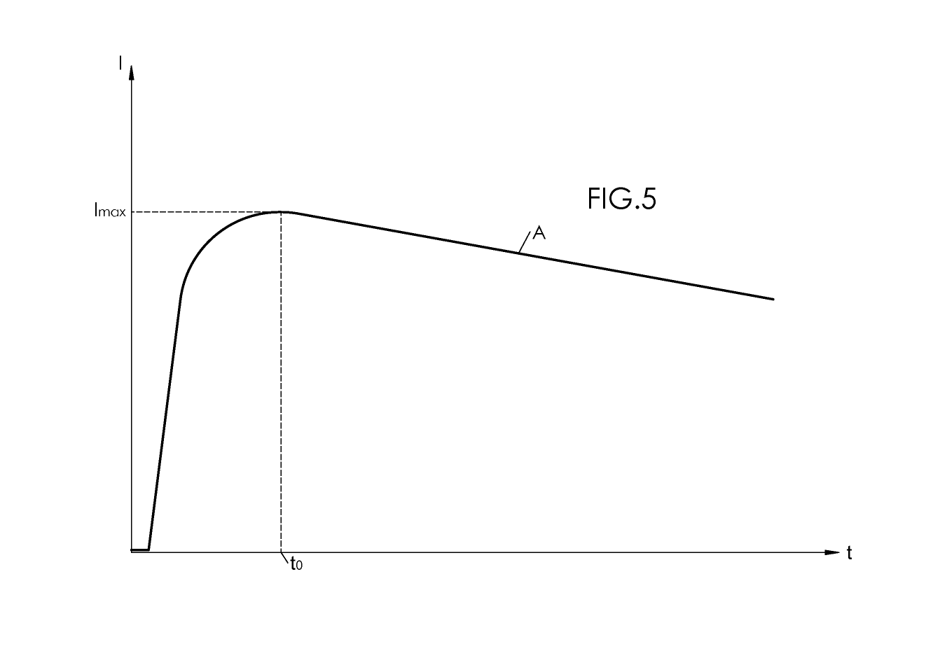

FIG. 5 is a diagram on which is drawn a curve corresponding to the variations in luminosity in the container over time.

Partially represented in FIG. 1 is an installation 1 for treating containers 2 made of polymer by plasma-assisted chemical vapor deposition, on an inner wall of the containers 2, of a thin barrier layer.

Each container 2 to be treated (typically a bottle or a jar) has its final shape; it has, for example, been formed by blow molding or stretch blow molding from a preform. According to a particular embodiment, the container 2 is made of PET (polyethylene terephthalate).

The layer to be deposited can be composed of hydrogenated amorphous carbon, which has the advantage of forming a barrier to gases such as oxygen and carbon dioxide, to which PET alone is relatively permeable. Types of thin layers other than those having a carbon base may be suitable, for the same applications, particularly having a base of silicon oxide or aluminum oxide.

The installation 1 comprises a plurality of treatment stations 3 that are all similar, each one configured to receive and treat a single container 2 at a time. The installation 1 further comprises a structure (preferably rotating, such as a carousel) on which the treatment stations 3 are mounted, which number, for example, twenty-four, or else forty-eight, so as to make possible a treatment of the containers 2 at an industrial rate (on the order of several tens of thousands per hour).

Each treatment station 3 comprises an outer cavity 4 that is advantageously cylindrical in shape, made of a conductive material, for example metal (typically steel or, preferably, aluminum or an alloy of aluminum), and dimensioned to make possible the establishment in it of a stationary electromagnetic wave at a predetermined resonance frequency in the range of the microwaves, and more specifically close to 2,450 MHz (or 2.45 GHz).

Each treatment station 3 further comprises a tubular enclosure 5, mounted coaxially and fluid-tight in the cavity 4 and made of a material that is transparent to a wide electromagnetic spectrum. More specifically, the enclosure 5 is transparent at least to the visible range and to microwaves. According to an embodiment, the material from which the enclosure 5 is made is quartz.

According to a particular embodiment illustrated in FIG. 3, the enclosure 5 is, at an upper end, fitted tightly into an opening formed in an upper wall of the cavity 4, it being topped by a cover 6.

At a lower end, the enclosure 5 works tightly with a removable bottom that makes it possible to introduce, through the bottom, a container 2 into the enclosure 5 to make possible its treatment, and its withdrawal after the end of the treatment.

The treatment station 3 is equipped with a support (for example of a fork type) that works with a neck of the container 2 to ensure its suspension in the enclosure 5, and various seals that ensure the fluid-tightness of the inner space of the container 2 with respect to the enclosure 5.

Thus, separated in a fluid-tight manner are:
the interior of the container 2,
the exterior of the container 2 in the enclosure 5,
the exterior of the enclosure 5 in the cavity 4.

For more detail on achieving the fluid-tightness, a person skilled in the art can refer to the description of the patent application US 2010/0007100.

The treatment station 3 comprises:
a primary vacuum circuit comprising a primary vacuum pump 7 making it possible to create a high vacuum (on the order of several microbars) in the container 2, via a pipe 8 made in the cover 6 and that comes out into the container 2 (when it is present), and
a secondary vacuum circuit comprising a secondary vacuum pump making it possible to create a middle-level vacuum (on the order of several millibars) in the enclosure 5 on the outside of the container 2, to prevent it from contracting under the effect of the difference in pressure on both sides of its wall.

The treatment station 3 also comprises a device 9 for injecting, into the enclosure 5, a precursor gas such as acetylene (with the formula C₂H₂). In the example illustrated, this device 9 comprises a tubular injector 10 connected, via a flexible hose 11 and a controlled solenoid valve 12, to a source (not shown) of precursor gas.

For more detail concerning the structure of the cavity 4, a person skilled in the art can refer to the description of the patent application US 2010/0206232 (Sidel Participations).

The treatment station 3 also comprises at least one sensor 13 associated with the enclosure 5 and able to perform a measurement of a physical magnitude characterizing the energy intensity of a plasma triggered within the precursor gas.

According to a particular embodiment illustrated in the figures, the sensor 13 is a luminosity sensor. The luminosity is directly proportional to the energy intensity of the plasma. The enclosure 5, transparent to the visible range of the electromagnetic spectrum, does not form an obstacle to the diffusion of the light coming from the plasma and therefore does not affect (or affects very little) the measurement.

The sensor 13 can be mounted on the wall of the cavity 4. As is seen in FIG. 4, the sensor 13 is connected to a control unit 14 that collects the measurements from it. The control unit 14 is computerized (in the form of a programmable logic controller, of a computer or more simply of a processor); it can be specific to the treatment station 3 or common to all of them (provided that its computing power is sufficient).

In a variant, the sensor 13 can be a spectrometer (mass spectrometer, optical spectrometer or else ionic spectrometer), capable of measuring the mass concentrations of the different species contained in the plasma (and therefore deducing from it the energy intensity of it), or a pressure sensor (the pressure being inversely proportional to the intensity of the plasma). In this latter case, the sensor is mounted on the pipe 8.

The treatment station 3 furthermore comprises a generator 15 of electromagnetic waves in the microwave range. It is a generator known as “solid state.”

The expression “solid state,” rarely used in French, is a literal translation of the English expression “solid state,” used currently for decades in the field of electronics, and more particularly in the field of radiofrequency engineering, as the following works show:
Herbert L. Kraus et al. “Solid-State Radio Engineering,” Ed. John Wiley & Sons, 1980.
Stephen F. Adam, “Microwave Theory and Applications,” Englewood Cliffs, 1969.
Owen E. Maynard, “Solid-State SPS Microwave Generation and Transmission Study,” NASA Scientific and Technical, 1980.

In a general way, the expression “solid state” characterizes a state of the material in which the atoms, molecules or ions are linked to one another so that in the absence of mechanical stress, they are fixed relative to one another. In electronics, the expression “solid state” designates the circuits manufactured using solid materials and in which the electrons or other carrier charges of a signal are confined in these materials. Today, these circuits are more commonly called “integrated circuits” or “semi-conductor circuits,” but the expression “solid state” has remained to characterize certain complex electronic devices.

Thus, a solid-state microwave generator designates a device for generating an electrical signal in the microwave frequency range, in which the signal is generated by an integrated circuit, in contrast with the older (but still used) technologies of vacuum tubes (used particularly in the magnetron-type generators).

Generators known as “solid state” are available under this designation commercially, see for example:
at SAIREM, the model GMS 200 W solid-state microwave generator, which furnishes a microwave signal with a central frequency of 2,450 MHz, adjustable between 2,430 and 2,470 MHz, for a maximum output power of 200 W;
at MKS, the model SG 524 solid-state microwave generator, which furnishes a microwave signal with a central frequency of 2,450 MHz, adjustable between 2,400 and 2,500 MHz, for a maximum output power of 450 W.

It does not enter into the scope of this specification to furnish a precise description of a solid-state microwave generator, since, as we have just seen, models of such generators exist commercially and can be incorporated without special adaptation to this installation.

However, it may seem useful, for a better understanding of the phenomena in play, to furnish a succinct description of the structure of a possible embodiment of the solid-state microwave generator 15, with reference to FIG. 4.

This generator 15 is of the optoelectronic type, but this technology is in no way limiting. Thus, a transistor LC oscillator generator could be used, whose inductance is variable (which makes it possible to have vary the frequency of the microwaves generated).

Be that as it may, in the example illustrated, the generator 15, of the optoelectronic type, comprises, firstly, the following components:
a light-emitting diode 16, for example a continuous wave or CW laser diode, which converts an electric power supply signal into a light signal that is non-modulated in intensity;
a semiconductor modulator 17 (of the Mach-Zehnder type, for example), which modulates in intensity the non-modulated light signal coming from the light-emitting diode 16;
an optical wave guide 18, into which the light modulated by the modulator 17 is injected; this wave guide 18 comprises, for example, an optical fiber;
a semiconductor photoreceptor 19, such as an MSM (metal-semiconductor-metal) diode, which captures the modulated light signal coming from the wave guide 18 and converts it into an electrical signal;
optionally a semiconductor preamplifier 20 (preferably having a field effect transistor, for example having a MESFET transistor—a metal-semiconductor field effect transistor), which assigns to the power of the electrical signal coming from the photoreceptor 19 a coefficient of proportionality greater than 1;
a coupler 21, which takes a portion of the electrical signal coming from the photoreceptor 19 (optionally amplified by the preamplifier 20) to reinject it into the modulator 17 (which is thus attached), so as to form a feedback loop that causes a sustained oscillation of the optical signal coming from the modulator 17 (and therefore of the electrical signal coming from the photoreceptor 19).

These components thus form, together, an oscillator that supplies, as output, a periodic electrical signal whose frequency is located in the microwave range. More specifically, according to a preferred embodiment, the components are selected so that the frequency is in the 2,400 MHz-2,500 MHz ISM (Industrial, Scientific, Medical) band as defined by the standard EN 55011.

As is seen in FIG. 4, the wave guide 18 comprises a variable frequency drive 22 consisting of a variable length section that, by modifying the length of the path traveled by the light signal, causes a variation in its frequency. In other words, the variable-length section of the wave guide forms a variable frequency drive 22 for the signal coming from the oscillator, so as to cover the 2,400 MHz-2,500 MHz range. The variable frequency drive 22 is connected to the control unit 14.

The generator 15 comprises, secondly, an amplifier 23 that receives the electrical signal coming from the oscillator to apply to it a coefficient of proportionality (greater than 1) and thus to increase its power. The amplifier 23 is of the semiconductor type. It is, for example, a transistor circuit. According to a preferred embodiment, this amplifier 23 comprises a field effect transistor, such as a MOSFET transistor (a field effect transistor having a metal-oxide-semiconductor structure).

The treatment station 3 then comprises a device 24 for diffusion of microwaves in the cavity 4 (therefore in the enclosure 5, transparent to the microwaves), connected to the generator 2 by a branched coaxial cable 25 as output of the oscillator or, when it exists, of the amplifier 23. According to an embodiment illustrated in FIGS. 1 to 4, this diffusion device 24 appears in the form of an antenna that extends through the wall of the cavity 4 and projects into it. The antenna 24, mounted at the end of the coaxial cable 25 opposite the generator 15, has the function of converting the electrical signal received from the generator 15 (and relayed by the coaxial cable 25) into a microwave electrical field in the cavity 4.

As FIGS. 2 and 3 clearly show, this antenna 24, made from a metal material (for example of copper or of aluminum), forms a loop in the cavity 4 to make a magnetic coupling with it. The dimensions of this loop are on the same order of magnitude as the half-wavelength of the signal (the wavelength is on the order of 12.2 cm).

The propagation of the microwaves in the cavity 4 is free, and the reflections on the walls of the cavity 4 produce a superposition of incident and reflected waves, and the establishment in the cavity 4, for certain frequencies, of a stationary microwave electrical field, whose spatial distribution is not uniform and that, in certain zones, has local concentrations of energy. Different modes of propagation (called resonant modes) are able to produce a stationary field. These resonant modes differ from one another by spatial localization, in the cavity 4, of concentrations of energy.

The resonant modes depend on the transmission frequency of the microwaves in the cavity 4 and on its geometry, which in this case is cylindrical. The resonant modes for this geometry are relatively well known, which has the advantage of correctly selecting a first resonant mode, called injector mode, making it possible to achieve a microwave energy concentration around the injector 10 in the absence of a container and of plasma.

This injector mode makes it possible then to obtain, by successive approaches and by variation of the frequency of the microwaves, a second resonant mode (called container mode) making it possible to achieve a microwave energy concentration around the injector 10 in the presence of a container but in the absence of plasma, and making it possible to trigger it, and then a third resonant mode (called plasma mode) making it possible to sustain the plasma thus generated.

The injector mode is a resonant mode corresponding to the cavity 4 associated with the injector 10 (but in the absence of a container and plasma). The injector mode is characterized by energy nodes distributed at a pitch equal to the half-wavelength of the microwaves (or a pitch of 6.1 cm for a wavelength of 12.2 cm). The injector mode is derived from the TM₀₂₀ mode (resonant mode of the magnetic transverse type, having localized energy concentration on the central axis of the cavity 4).

For more specification on the subject of the resonant modes in the microwave cavities, a person skilled in the art can consult the work of Mehrdad Mehdizadeh, “Microwave/RF Applicators and Probes for Material Heating, Sensing, and Plasma Generation,” Elsevier, 2010.

As already indicated, the reflections of the microwaves on the walls of the cavity 4 produce reflected waves. These reflected waves are picked up by the antenna 24 (which then acts as a receptor) and converted by it into a reflected electrical signal, which can circulate in the coaxial cable 25.

The presence of the reflected signal causes a loss of power and the reduction of energy available to generate and sustain the plasma. The reflected signal can be measured by means of a bolometer, or else by means of a device 26 for measuring power (commonly called a wattmeter) mounted, along the coaxial cable 25, between the generator 15 and the antenna 24.

The wattmeter 26 is configured to measure the total power of the signal passing through the coaxial cable 25. This total power is equal to the power of the incident signal increased by the power of the reflected signal.

Since the power delivered by the generator 15 is known, the measurement of the total power of the signal passing through the coaxial cable 25 makes it possible, by simple subtraction, to calculate the power of the reflected signal. As illustrated in FIG. 4, the wattmeter 26 is connected to the control unit 14, which ensures the collection of the measurements and the subsequent calculations.

A nominal value of reflected power corresponds to each resonant mode. Each one of these powers can be evaluated by means of electromagnetic simulation software, for example ANSYS HFSS, in which the characteristics of the cavity 4 and the power of the incident microwave electrical signal are introduced. Thus, it is possible to establish a database containing, for the model of the cavity 4, and at a given incident power, a list of reflected powers, each one characteristic of a resonant mode. In particular, it is possible to extract from this list a theoretical reflected power corresponding to the injector mode.

It is then possible to perform a procedure for frequency pre-calibrating of the generator 15, during which a transmission frequency of the microwaves is sought for which, in the absence of the container 2, the cavity 4 associated with the injector 10 resonates according to the injector mode.

The pre-calibrating procedure, performed in the absence of container 2 in the cavity 4 associated with the injector 10, and also in the absence of precursor gas, comprises at least one measurement cycle during which the cavity 4 is supplied with microwaves, and a frequency scan is performed on the entire eligible spectrum for the generator 15 (such as 2,400 MHz-2,500 MHz), to identify in this spectrum a frequency for which the reflected power is equal (or approximately equal) to the theoretical reflected power of the injector mode.

In the case where the pre-calibrating procedure comprises a single measurement cycle, the value of the single frequency for which the reflected power is equal (or approximately equal) to the theoretical reflected power of the injector mode is assigned to the desired frequency (denoted F and called injector modal frequency).

According to a preferred embodiment, the pre-calibrating procedure comprises a series of N (N a sufficiently large integer to obtain a significant statistical population) cycles of successive measurements, making it possible to collect a population of N injector modal frequencies, denoted Fᵢ (i an integer designating the number of the cycle, 1≤i≤N), for which, during each cycle, the power of the reflected signal is equal (or approximately equal) to the theoretical reflected power of the injector mode.

Only one value is then retained for the desired frequency (also denoted F and called injector modal frequency): the average of the primary modal frequencies Fᵢ:

$$F = \frac{1}{N} {\sum }_{i = 1}^{N} {F}_{i}$$

The pre-calibrating procedure is performed for each cavity 4 (and each associated generator 15) of the installation 1. This procedure can be performed at the factory (i.e., not during production).

Then, a procedure for frequency calibrating of the generator 15 is performed, during which:
a new frequency for transmission of the microwaves is sought for which the cavity 4 resonates, this time in the presence of a container 2, according to the container mode;
a comparison is made with the injector modal frequency to deduce from it an offset to it.

A first (measuring) phase of the calibrating procedure is approximately identical to the pre-calibrating procedure described above but differs from it by the presence, in the cavity 4 (and more specifically in the enclosure 5), of a container 2 that, by the dielectric nature of its material, assigns the energy distribution of the microwave power within the cavity 4, and therefore gives rise to an offsetting of the transmission frequency of the microwaves for which the cavity 4 resonates according to the container mode.

Thus, the calibrating procedure comprises, in the presence of a container 2 and of the injector 10, and in the absence of the conditions necessary for triggering a plasma (for example in the absence of precursor gas, or with a reduced gas flow, or with insufficient microwave power, or even with insufficient vacuum—i.e., at an excessive pressure—in the container 2), at least one measuring cycle during which the cavity 4 is supplied with microwaves and a frequency scan is again performed on the entire eligible spectrum for the generator 15 (here, 2,400 MHz-2,500 MHz), to identify in this spectrum a new frequency for which the reflected power is equal (or approximately equal) to the theoretical reflected power of the container mode.

In the case where, like the pre-calibrating procedure, the calibrating procedure comprises a single measuring cycle, the value of the single frequency for which, in the presence of a container 2 in the cavity 4, the reflected power is equal (or approximately equal) to the theoretical reflected power of the container mode, is assigned to the new desired frequency (denoted F′ and called container modal frequency).

Then the offset, denoted D, of the container modal frequency to the injector modal frequency, equal to their difference, is calculated:

D=F′−F

According to a preferred embodiment, the calibrating procedure instead comprises a series of P (P an integer, which can be equal to N) cycles of successive measurements, making it possible to collect a population of P container modal frequencies, denoted F′ᵢ (i an integer designating the number of the cycle, 1≤i≤P), for which, during each cycle, the power of the reflected signal is equal (or approximately equal), in the presence of a container 2 in the cavity 4, to the theoretical reflected power of the container mode.

In this case, calculated for each frequency F′ᵢ is its offset, denoted Dᵢ, at the injector modal frequency F, equal to the absolute value of their difference, as well as the average offset, denoted D as before, of the offsets D′ᵢ:

$${D}_{i} = {F}_{i}^{′} - F$$

$$D = \frac{1}{P} {\sum }_{i = 1}^{P} {D}_{i} = \frac{1}{P} {\sum }_{i = 1}^{P} ( {F}_{i}^{′} - F )$$

According to a particular embodiment, it is also possible, in this case, to calculate the standard deviation, denoted σ, of the population of the offsets Dᵢ to the average offset D:

$$σ = \sqrt{\frac{1}{P} {\sum }_{i = 1}^{P} {( {D}_{i} - D )}^{2}}$$

The calibrating procedure is performed for each cavity 4 (and each associated generator 15) of the installation 1.

The pre-calibrating and calibrating procedures make it possible to select, from the entire microwave spectrum allowed by the generator 15 (here 2,400 MHz-2,500 MHz), a range of microwave frequencies (called effective triggering range) that can excite the cavity 4 according to the container mode, and therefore, as a result of the concentration of power that this mode generates in the center of the container 2, to trigger the plasma in the precursor gas.

When the pre-calibrating and calibrating procedures comprise only a single measuring cycle, the effective triggering range is:

[F−|D|;F+|D|]

When the pre-calibrating and calibrating procedures comprise several (respectively N and P) measuring cycles, the effective triggering range is:

[F+|D|−3σᵢF+|D|+3σ]

A start-up procedure is then provided, which aims to identify, from the effective triggering range, a frequency, called start-up and denoted F₀, making it possible to trigger and to sustain a plasma in the container 2.

It is assumed that the treatment station 3 is in proper working order, i.e., that a container 2 to be treated is present in the enclosure 5, that a high vacuum has been made there, that a middle-level vacuum has been achieved in the enclosure 5, that the injector 10 is in place in the container 2 and that the precursor gas is ready to be injected into the container 2.

According to a first embodiment, the precursor gas is injected into the container 2, the generator 15 is switched on, and the transmission frequency of the microwaves is adjusted (via the control unit 14 acting on the variable frequency drive 22) to any value selected from the effective triggering range (for example F+|D|).

Next, the transmission frequency of the microwaves is then adjusted by the control unit 14, via the variable frequency drive 22, until the intensity of the plasma deduced from the measurement made by the sensor 13 exceeds a predetermined threshold, marking the presence of a plasma in the container 2. This threshold, stored in the control unit 14, has, for example, a zero or essentially zero value (which corresponds to the darkness in the cavity 4).

The plasma results from the molecular decomposition of the precursor gas by the microwave energy concentrated in the center of the container 2 as a result of the container mode. The molecular decomposition of the precursor gas (in this case, acetylene) produces a soup of assorted volatile CₓH_{y}-type species, where x and y are real with x≥0 and y≥0, at least a portion of which is ionic.

The molecular decomposition of the precursor gas produces photons particularly in the visible range of the electromagnetic spectrum, which makes the plasma luminous and therefore detectable in this range. However, it is a plasma called “cold” (or of low energy), in which the volatile species coming from the molecular decomposition of the precursor gas remain at ambient temperature.

The at least partially ionic nature of the plasma imparts to it a non-zero electric conductivity that, being coupled to the electric and magnetic fields prevailing in the enclosure 5, assigns the spatial distribution of the microwave energy because of the variation of dielectric permittivity of the medium in which the microwaves propagate. An extinction of the plasma can result therefrom, although the spatial distribution of the microwave energy is assigned to the point where the energy density in the center of the container 2 is insufficient to sustain the plasma.

However, after the CₓH_{y} species of the plasma are deposited on the inner wall of the container 2 (thus contributing to the generation of a thin layer of hydrogenated amorphous carbon), or have been pumped outside of the container 2 by the primary vacuum circuit, the precursor gas again becomes predominant in the container 2, and the spatial distribution of the energy can recover its initial geometry, corresponding to the container resonant mode, which makes possible a re-triggering of the plasma.

The successive triggerings and extinctions of the plasma take place rapidly (in less than one-tenth of a second), so that a flickering phenomenon in the container 2 is found using the sensor 13. When the sensor 13 is a luminosity sensor, it detects successively a positive luminosity (at the triggering of the plasma) and a zero luminosity (at its extinction).

Such a flickering is to be avoided because, although it does not, in theory, prevent the depositing of the species on the inner wall of the container 2 (and therefore the formation of the barrier layer), the treatment time required is much too long for a production at an industrial rate. The deposited layer can further have inhomogeneities, due to a poor distribution of the species in the container, resulting from the insufficient duration of the triggered plasma at each flicker.

Consequently, it is understood that it is not enough to find a frequency value within the effective triggering range, which makes it possible to initiate the plasma, but that it is necessary then to adapt this frequency so that it also makes it possible to sustain the plasma.

For this purpose, the start-up procedure comprises an adjusting phase during which the control unit 14 controls a frequency scan, via the variable frequency drive 22, from the first value (for example, by an increment of 1 MHz or of 0.1 MHz), until obtaining a frequency making it possible to sustain the plasma. It is conceivable to abide by this approach, and to store this frequency as a frequency for sustaining the plasma.

However, this approach can appear insufficient, because it may be desired to find, within the effective triggering range, a frequency value that makes it possible not only to sustain the plasma but also to minimize the treatment time, at the end of which the thickness of the layer that has been deposited on the inner wall of the container 2 is presumed sufficient (on the order of ten to several hundreds of nm—remember that 1 nm=10⁻⁹ m) to obtain the desired barrier effect.

For this purpose, it is necessary to maximize the energy density at the center of the container 2, which amounts to minimizing the reflected power.

In practice, the start-up procedure in this case comprises an adjusting phase (different from the preceding one) during which the control unit 14 controls a frequency scan of the entire effective triggering range, (for example from the minimum limit to the maximum limit), by a predefined increment (for example, 1 MHz or 0.1 MHz), with, for each frequency, a predetermined measuring time (for example, of several tens of milliseconds).

For each frequency, the control unit 14 raises, via the wattmeter 26 and the sensor 13, respectively the reflected power (to be minimized) and the intensity of the plasma in the cavity 4 (which must be absolutely positive during the measuring time).

The values of reflected power and of energy intensity of the plasma are stored by the control unit 14. Then, this unit selects, at the end of the scan cycle, the frequency that, having positive energy intensity, creates the weakest reflected power. This frequency is then stored as frequency F₀ by the control unit 14 for sustaining the plasma.

Once defined, the frequency F₀ for each cavity 4 (i.e., for each generator 15), the production process (i.e., treatment of the containers 2 at an industrial rate) in the installation 1 can start up, the control unit 14 adjusting for each generator 15 the transmission frequency of the microwaves at the predefined value F₀ for it.

It is further possible to provide, either during the production, or during a pre-production phase (at the end of which the containers 2, which can have defects from treatment, are not intended for sale), an adjusting procedure during which the following can be adjusted:
the transmission frequency of the microwaves to adapt the resonant mode in the cavity 4 to the variations in intensity of the plasma—this frequency variation can be considered as directly proportional to the intensity of the plasma (deduced from the measurements made by the sensor 13);
the degree of vacuum in the container 2;
the flow of precursor gas;
the power of the generator 15.

The speed of growth of the barrier layer during treatment actually depends on these four parameters. By causing them to vary, it is possible to increase the rate of production by increasing the speed of growth of the barrier layer.

The speed of growth of the barrier layer can be measured by the variation of the energy intensity of the plasma measured during treatment by the sensor 13. Actually, the barrier layer gradually darkens the inner wall of the container 2, so that the luminosity measured diminishes during treatment, with continued growth of the barrier layer.

It is possible, from a series of measurements of luminosity taken during the treatment of a container 2 and stored by the control unit 14, to construct by interpolation (particularly polynomial) a curve of the variations in luminosity during the treatment. Starting from the zero value (before the triggering of the plasma), the curve shows a peak (corresponding to the triggering of the plasma) followed by a linear decrease (corresponding to the growth of the barrier layer and to the gradual darkening of the wall of the container 2).

Drawn in FIG. 5 is a curve illustrating the variations in luminosity caused by the plasma in the cavity 4. This curve shows a luminosity peak with a value lₘₐₓ at a time t₀, and then a slope A having a (negative) rate of increase.

As has been seen, the transmission frequency of the microwaves has an impact on the microwave energy density within the cavity 4, and consequently influences the intensity of the plasma (particularly at triggering) and therefore the speed of growth of the barrier layer. However, all parameters being equal furthermore, the function binding the transmission frequency of the microwaves to the speed of growth of the barrier layer is to date unknown, and only tests make it possible to optimize the latter.

The manner in which the transmission frequency of the microwaves can be adjusted (by the control unit 14 via the variable frequency drive 22) has already been described.

The control unit 14 can be programmed to control (via the variable frequency drive 22), starting from the frequency F₀, an adjustment of the transmission frequency of the microwaves until obtaining a corrected frequency F₀ that maximizes the luminous intensity lₘₐₓ at the triggering and/or that maximizes the speed of growth of the barrier layer (by causing the slope A to vary). This fine adjustment can be made (for example, by incremental variations on the order of 1 to 10 kHz) to maintain a minimum reflected power and to avoid assigning the energy distribution in the cavity 4 to the point that the plasma is not extinguished or does not start flickering.

Increasing the degree of vacuum in the container 2 and/or the flow of the precursor gas makes it possible to increase the density of precursor gas in the container 2 (and therefore the energy intensity of the plasma as well as the speed of growth of the barrier layer).

To make possible an adjustment of the degree of vacuum in the container 2, the treatment station 3 comprises a pressure sensor 27 mounted in the cover 6 and coming out into the pipe 8 (where the pressure is equal to that prevailing in the container 2), and the vacuum pump 7 is attached to the control unit 14 that can thus adjust the flow.

The control unit 14 can be programmed to control (via the flow of the vacuum pump 7) an adjustment of the degree of vacuum in the container 2 until obtaining a flow value that maximizes the luminous intensity lₘₐₓ at the triggering and/or that maximizes the speed of growth of the barrier layer.

To make possible an adjustment of the flow of precursor gas, the solenoid valve 12 of the injection device 9 is attached to the control unit 14 that controls its opening.

The control unit 14 can be programmed to control (via the solenoid valve 12) an adjustment of the flow of precursor gas until obtaining a flow value that maximizes the luminous intensity lₘₐₓ at the triggering and/or that maximizes the speed of growth of the barrier layer.

Increasing the power of the microwave signal delivered by the generator 15 also makes it possible to increase the intensity of the plasma and the speed of growth of the barrier layer.

The power can be adjusted via a variable power drive incorporated in the generator 15, and controlled by the control unit 14. The control unit 14 can thus be programmed to control an adjustment of the power of the microwaves delivered by the generator 15 to increase the luminous intensity in the triggering and/or the speed of growth of the barrier layer.

From a practical point of view, the generator 15 can be equipped with a single input/output port to which a bus 28 (for example of the universal serial type or USB type) can be connected for the connection of the control unit 14.

In this case, the distribution of the control signals is performed downstream from the input/output port by an electronic control (typically a mother board) of the generator 15, to assign the frequency control signal to the variable frequency drive 22, and the power control signal to the variable power drive. These signals can be transmitted by the control unit 14 on the same bus 28 by being, for example, interlaced by means of a time division multiplexing (or TDM) algorithm.

The use of a solid-state generator to trigger and sustain a plasma in the treatment of containers by chemical vapor deposition provides several advantages.

Firstly, the possibility of frequency adjustment of the solid-state generator avoids difficult pairing tests between generator (of the magnetron type) and cavity, benefiting the simplification of design and assembly of the machines for plasma treatment of the containers. Secondly, the automatic frequency adjustment makes it possible to generate—in a simpler, faster and more certain manner—a resonant mode favorable to the triggering and sustaining of the plasma, benefiting the reliability of the machine. Thirdly, the frequency adjustment makes it possible, by selection of the most effective resonant modes, to improve the quality of the plasma treatment of the containers while avoiding the phenomena of flickering.

1. Installation (1) for the plasma-assisted chemical vapor deposition—on an inner wall of a container (2) made of polymer—of a thin barrier layer, which comprises:
a conductive cavity (4);
an enclosure (5) mounted in the cavity (4);
a device (9) for injecting a precursor gas into the enclosure (5);
a generator (15) of microwaves;
a device (24) for diffusion of the microwaves in the enclosure (5), connected to the microwave generator (15), to excite and sustain a plasma in the precursor gas;
wherein:
the microwave generator (15) is a solid-state generator, equipped with a variable frequency drive (22) for transmission of microwaves;
the installation comprises a sensor (13) positioned so as to measure a physical magnitude characterizing the energy intensity of the plasma produced in the container (2);
the installation comprises a control unit (14) connected to the sensor (13) and to the microwave generator (15), this control unit (14) being programmed to adjust the transmission frequency of the microwaves, by means of the variable frequency drive (22), as a function of the value of the physical magnitude characterizing the energy intensity measured by the sensor (13).

2. Installation (1) according to claim 1, wherein the sensor (13) is a luminosity sensor directed toward the enclosure (5) so as to measure the luminosity through the wall of the enclosure (5) and that of the container (2).

3. Installation (1) according to claim 1, wherein the sensor (13) associated with the enclosure (5) is a spectrometer positioned to measure the mass concentrations of the different species contained in the plasma produced in the container (2).

4. Installation (1) according to claim 1, wherein the sensor (13) associated with the enclosure (5) is a sensor of the pressure of the plasma prevailing in the container (2).

5. Installation (1) according to claim 1, wherein the device (24) for diffusion of the microwaves appears in the form of an antenna.

6. Installation (1) according to claim 5, wherein the antenna (24) extends through the cavity (4) and projects into it.

7. Installation (1) according to claim 5, wherein the antenna (24) forms a loop in the cavity (4).

8. Installation (1) according to claim 7, wherein the dimensions of the loop formed by the antenna (24) are of the same order of magnitude as the half-wavelength of the microwaves produced by the generator (15).

9. Installation according to claim 1, wherein the device (24) for diffusion of the microwaves is connected to the generator (15) by a coaxial cable (25).

10. Method for adjusting an installation (1) according to claim 1, which comprises the operations consisting in:
introducing a container (2) into the enclosure (5);
injecting the precursor gas into the container (2);
generating in the enclosure (5), by means of the microwave generator (15), an electromagnetic field with a predetermined transmission frequency so as to excite a plasma in the precursor gas;
measuring a physical magnitude characterizing the energy intensity of the plasma produced in the container by means of the sensor (13);
as long as the physical magnitude characterizing the energy intensity of the plasma produced in the enclosure (5) differs from a predetermined reference value, adjusting the transmission frequency of the microwaves by means of the control unit (14) acting on the variable frequency drive (22).

11. Adjusting method according to claim 10, wherein the physical magnitude measured is proportional to the value of the energy intensity.

12. Adjusting method according to claim 11, wherein the physical magnitude measured is the luminosity of the plasma.

13. Adjusting method according to claim 11, wherein the physical magnitude measured is the mass concentration of the species contained in the plasma.

14. Adjusting method according to claim 10, characterized in that the physical magnitude measured is inversely proportional to the energy intensity.

15. Adjusting method according to claim 14, wherein the physical magnitude measured is the pressure prevailing in the container (2).

16. Installation (1) according to claim 2, wherein the device (24) for diffusion of the microwaves appears in the form of an antenna.

17. Installation (1) according to claim 3, wherein the device (24) for diffusion of the microwaves appears in the form of an antenna.

18. Installation (1) according to claim 4, wherein the device (24) for diffusion of the microwaves appears in the form of an antenna.

19. Installation (1) according to claim 6, wherein the antenna (24) forms a loop in the cavity (4).

20. Installation according to claim 2, wherein the device (24) for diffusion of the microwaves is connected to the generator (15) by a coaxial cable (25).
